(19) United States
(12) Patent Application Publication
(10) Pub. No.: US 2017/0276733 A1
(43) Pub. Date: Sep. 28, 2017

(54) METHOD FOR SCREENING LITHIUM ION BATTERY

(71) Applicants: Jiangsu Huadong Institute of Li-Ion Battery Co., Ltd., Suzhou (CN); Tsinghua University, Beijing (CN)

(72) Inventors: Yong Yang, Suzhou (CN); Hong-Sheng Zhang, Suzhou (CN); Xiang-Ming He, Beijing (CN); Jian-Jun Li, Beijing (CN); Tuan-Wei Li, Suzhou (CN); Guo-Hua Li, Suzhou (CN); Shu-Hui Wang, Suzhou (CN); Li Wang, Beijing (CN)

(73) Assignees: Jiangsu Huadong Institute of Li-Ion Battery Co., Ltd., Suzhou (CN); Tsinghua University, Beijing (CN)

(21) Appl. No.: 15/618,086

(22) Filed: Jun. 8, 2017

Related U.S. Application Data
(63) Continuation of application No. PCT/CN2015/096273, filed on Dec. 3, 2015.

(30) Foreign Application Priority Data
Dec. 9, 2014 (CN) 201410745443.3

(51) Int. Cl. G01R 31/36; H01M 10/44; H01M 10/48; H01M 10/0525

(52) U.S. Cl. CPC G01R 31/3627; G01R 31/3658; H01M 10/0525; H01M 10/441; H01M 10/482

(57) ABSTRACT

A method of screening a lithium ion battery is provided. A number of lithium ion batteries are galvanostatically discharged to a discharge cutoff voltage V₀ at a first constant current I₁. The number of lithium ion batteries are rested for a first rest time T₁. The number of lithium ion batteries are galvanostatically charged to a charge cutoff voltage V₁ at a second constant current I₂. The number of lithium ion batteries are rested for a second rest time T₂, and the batteries are screened based on a self-discharge of the plurality of lithium ion batteries.

### CROSS-REFERENCE TO RELATED APPLICATIONS

This application claims all benefits accruing under 35 U.S.C. §119 from China Patent Application No. 201410745443.3, filed on Dec. 9, 2014 in the State Intellectual Property Office of China, the contents of which are hereby incorporated by reference. This application is a continuation of international patent application PCT/CN2015/096273 filed Dec. 3, 2015, the content of which is hereby incorporated by reference.

### FIELD

The present disclosure belongs to the field of lithium ion batteries, and particularly relates to methods for screening lithium ion batteries.

### BACKGROUND

Lithium ion batteries as energy-saving products, having a high specific energy, a high cycle performance, and a low memory effect, have been widely used in photovoltaic energy storage, electric vehicles, electric tools, digital products, and other industries. The lithium ion batteries with a pollution-free feature have gradually replaced lead-acid batteries. Although a single lithium ion battery has a generally improved performance, the self-discharging rate of the lithium ion batteries in a module is still uneven. Even the single lithium ion battery can be cycled over 2000-3000 times, and the performance of the lithium ion battery module may be generally decreased by 15% due to the uneven self-discharging.

In assembling of the module, the lithium ion batteries are usually screened based on the capacity difference and the internal resistance difference.

### SUMMARY

The present disclosure provides a method for screening a lithium ion battery, the method comprising:

galvanostatic discharging a plurality of lithium ion batteries to a discharge cutoff voltage V₀ at a first constant current I₁;

resting the plurality of lithium ion batteries for a first rest time T₁ to restore an electrochemical system in each of the plurality of lithium ion batteries to a stable state;

galvanostatic charging the plurality of lithium ion batteries to a charge cutoff voltage V₁ at a second constant current I₂; and

resting the plurality of lithium ion batteries for a second rest time T₂, and screening the battery in which a self-discharge voltage decay of greater than 0.1 V.

The present disclosure provides a method for screening a lithium ion battery, the method comprising:

galvanostatic discharging a plurality of lithium ion batteries to a discharge cutoff voltage of the plurality of lithium ion batteries at a first constant current I₁;

resting the plurality of lithium ion batteries for a first rest time T1 to raise an open circuit voltage of the plurality of lithium ion batteries to U₂, wherein U₂ is smaller than an inflection point voltage;

galvanostatic charging the plurality of lithium ion batteries to the inflection point voltage at a second constant current I₂, wherein I₂<<I₁; and

resting the plurality of lithium ion batteries for a second rest time T2, and screening the battery based on a self-discharge of the plurality of lithium ion batteries, and removing large self-discharge batteries from the plurality of lithium ion batteries.

In the method for screening a lithium ion battery, the voltage decay caused by the different self-discharge has been fully considered, and the plurality of lithium ion batteries are at the same “starting” line before enter the second rest time. During the second rest time, the more the voltage decay, the larger the self-discharge performance. Thus the batteries having the large self-discharging performance can be removed.

### BRIEF DESCRIPTION OF THE DRAWINGS

FIG. 1 shows a schematic view of one embodiment of a method for screening a lithium ion battery.

FIG. 2 is a graphic showing voltage attenuations of a plurality of lithium ion batteries rest for 7 days.

FIG. 3 shows a schematic view of another embodiment of the method for a screening lithium ion battery.

FIG. 4 shows a schematic view of yet another embodiment of the method for screening a lithium ion battery.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein.

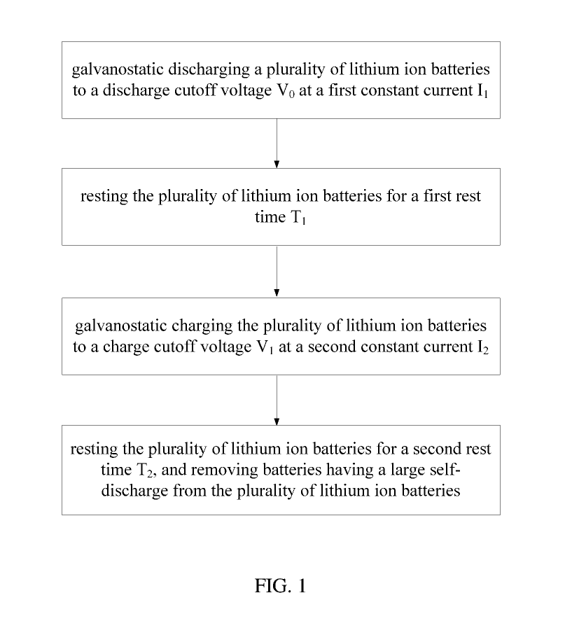

Referring to FIG. 1, a first embodiment of a method for screening a lithium ion battery comprises:

S10, galvanostatic discharging a plurality of lithium ion batteries to a discharge cutoff voltage V₀ at a first constant current I₁;

S11, resting the plurality of lithium ion batteries for a first rest time T₁;

S12, galvanostatic charging the plurality of lithium ion batteries to a charge cutoff voltage V₁ at a second constant current I₂; and

S13, resting the plurality of lithium ion batteries for a second rest time T₂, and removing batteries having a large self-discharge from the plurality of lithium ion batteries.

In step S10, the first constant current I₁ can be selected based on the capacity of the lithium ion battery. When the capacity of the lithium ion battery is C (unit: Ah), the first constant current I₁ can be in a range from about 0.5 C to about 1 C (unit: A). In one embodiment, the capacity of the lithium ion battery is 20 Ah, and the first constant current I₁ is 10 A. The discharge cutoff voltage V₀ can be 2.0 V to 3.0 V, and selected based on materials and discharge curves of the lithium ion battery to have a relatively stable remaining capacity of the lithium ion battery at the cutoff voltage. In one embodiment, the discharge cutoff voltage V₀ is 2.5 V.

In step S11, the first rest time T₁ can be in a range from about 5 minutes to about 10 minutes, and can be selected according to the sensitivity of the apparatus used and the degree of the electrochemical reaction to restore the electrochemical system in the battery to a stable state after the discharging of the lithium ion battery. Furthermore, the discharge current of the lithium ion battery in the stable state can be less than 0.2 mA. In one embodiment, the discharge current is less than 0.1 mA.

In step S12, the second constant current I₂ can be the same as or different from the first constant current I₁, and in a range from about 0.5 C to about 1 C. The second constant current I₂ can be selected according to the capacity of the lithium ion battery, in order to fully charge the lithium ion battery in a short time. In one embodiment, the second constant current I₂ is 10 A. The charge cutoff voltage V₁ is decided by the material of the lithium ion battery.

The charge cutoff voltage V₁ can be selected according to the material system and the charge and discharge curves of the lithium ion battery. The charge cutoff voltage V₁ can be 3.15 V, 3.10 V, 3.20 V, or 3.7 V. In one embodiment, the charge cutoff voltage V₁ is 3.10 V.

Furthermore, in one embodiment, when the lithium ion battery reaches the charge cutoff voltage V₁, the lithium ion battery can further be potentiostatically charged to a charge cutoff current I₀, which can be as small as possible, and can be in a range from about 0.001 C to about 0.04 C. Furthermore, the charge cutoff current I₀ can be in a range from about 0.01 C to about 0.02 C. In one embodiment, the charge cutoff current I₀ is 0.2 A. By reducing the charge cutoff current I₀, the charge cutoff voltage V₁ can be stabilized, and the misjudgment due to the instability of the current in the subsequence can be reduced.

In step S13, the second rest time T₂ can be in a range from about 5 days to about 12 days, which depends on the material of the lithium ion battery, in order to exhibit apparent self-discharge phenomenon. The lithium ion battery is mainly distinguished from each other based on the lithium-based cathode material, such as lithium iron phosphate, lithium nickel cobalt manganese oxide, or lithium manganese oxide. Thus the phenomenon of the self-discharge can be more obvious during the second rest time. During the removing of the lithium ion batteries, the standard of the large self-discharge can be decided according to need. In one embodiment, 0.1 V of the self-discharge voltage decay is taken as a standard, and the self-discharge voltage decay greater than 0.1 V is configured as the large self-discharge.

Referring to Table 1, taking a lithium iron phosphate battery having C=20 Ah for example, then 0.5 C=10 A, 0.1 C=2 A, . . . , 0.3 C=6 A, etc. The plurality of lithium ion batteries can be rest for a predetermined time before discharging the plurality of lithium ion batteries. The voltage of the lithium ion battery before discharging the plurality of lithium ion batteries is 3.4 V, so that the lithium iron phosphate battery is in a 50% state of charge (SOC).

TABLE 1
lithium iron phosphate battery screening process.

| | | Time | Voltage | Current | Cutoff |
|---|---|---|---|---|---|
| Step | Process | (min) | (V) | (A) | Current (A) |
| 1 | Rest | 5 | | | |
| 2 | Galvanostatic | 180 | 2.5 | 10 | |
| | Discharging | | | | |
| 3 | Rest | 5 | | | |
| 4 | Galvanostatic | 60 | 3.1 | 10 | 0.2 |
| | Charging | | | | |

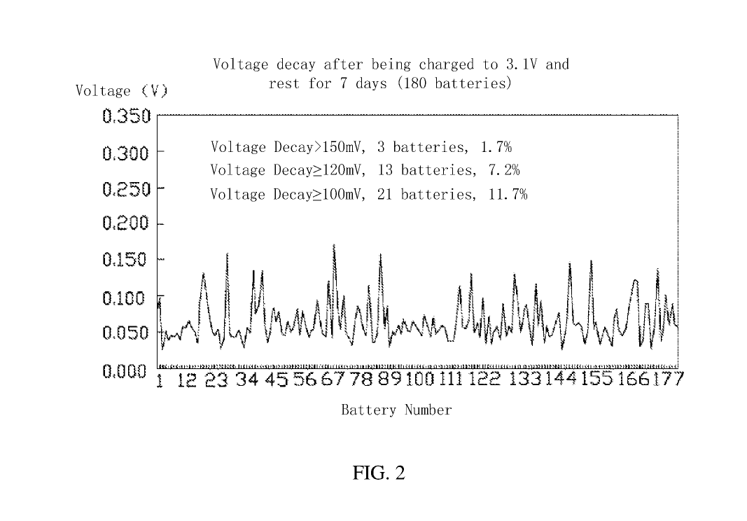

In one embodiment, 100 to 200 lithium iron phosphate batteries can be chosen for the data statistics. According to Table 1, after completing the steps 1-4, the batteries are rested for the second rest time T₂, such as 7 days. During the second rest time T₂, the voltage of the batteries can be tested. At the beginning of the second rest time T₂, an initial voltage of the lithium ion battery is 3.1V. In 7 days, the voltage of the lithium ion battery is tested for every predetermined time. Then the battery attenuation can be obtained, and the result is shown in FIG. 2.

During the second rest time T₂, the voltage decay is related to the initial voltage and length of the second rest time. The standard of the large self-discharge can be selected according to the actual needs. In one embodiment, while the lithium ion battery is discharged to 2.5 V and then charged to 3.1 V (the charge cutoff current is 0.01 C), it is assumed that after 7 days the voltage decay greater than or equal to 0.1 V is a relatively large self-discharge. The lithium ion batteries with large self-discharge can be clearly selected and removed according to this standard.

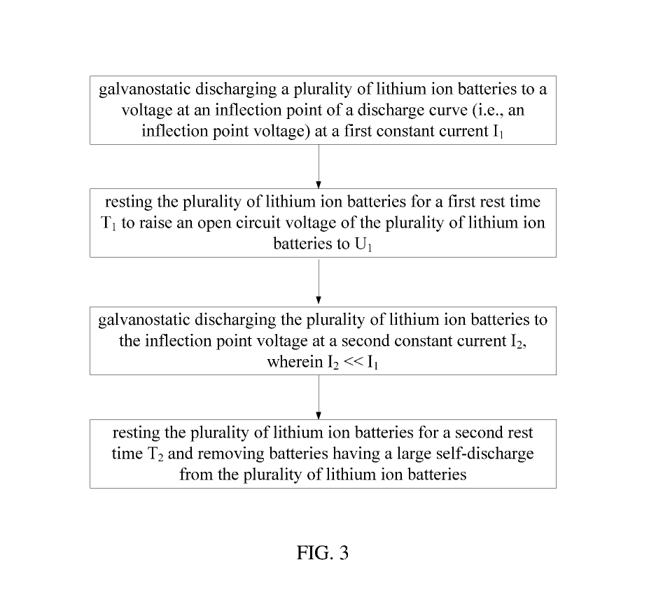

Referring to FIG. 3, a second embodiment of a method for screening a lithium ion batteries comprises the following steps:

S20, galvanostatic discharging a plurality of lithium ion batteries to a voltage at an inflection point of a discharge curve (i.e., an inflection point voltage) at a first constant current I₁;

S21, resting the plurality of lithium ion batteries for a first rest time T₁ to raise an open circuit voltage of the plurality of lithium ion batteries to U₁;

S22, galvanostatic discharging the plurality of lithium ion batteries to the inflection point voltage at a second constant current I₂, wherein I₂<<I₁; and

S23, resting the plurality of lithium ion batteries for a second rest time T₂ and removing batteries having a large self-discharge from the plurality of lithium ion batteries.

In step S20, the plurality of lithium ion batteries are discharged to the inflection point voltage 3.10 V of the discharge curve.

In step S21, the open circuit voltage can be raised by resting the battery for the first rest time T₁, and raised scale of the open circuit voltage is related to the discharge current. Specifically, the open circuit voltage can be raised to greater than the inflection point voltage of the discharge curve. In one embodiment, the open circuit voltage U₁ is about 3.15 V. Therefore, it is necessary to discharge again to bring the remaining capacity of the plurality of lithium ion batteries to a relatively stable state.

In step S22, unlike the first embodiment, the second constant current I₂ is much smaller than the first constant current I₁. In one embodiment, the second constant current I₂ is less than or equal to one fifth of the first constant current I₁. That is, the second constant current I₂ can be in a range from about 0.1 C to about 0.2 C. In one embodiment, the second constant current I₂ is 0.1 C, which is one fifth of I₁. The second constant current I₂ is the smaller the better, such as 0.01 C, 0.05 C, etc., but the discharge time will be increased. Table II is shown below.

TABLE II
lithium iron phosphate screening process

| | | Time | Voltage | Current | Cutoff |
|---|---|---|---|---|---|
| Step. | Process | (min) | (V) | (A) | Current (A) |
| 1 | Rest | 5 | | | |
| 2 | Galvanostatic | | 3.1 | 10 | |
| | Discharging | | | | |
| 3 | Rest | 5 | | | |
| 4 | Galvanostatic | 100 | 3.1 | 2 | 0.2 |
| | Discharging | | | | |
| 5 | Rest | 5 | | | |

Referring to Table II, the plurality of lithium ion batteries in the 50% state of charge can be discharged to 3.1 V in the same way as in the first embodiment, and the batteries having relatively large self-discharge are removed. Through analysis experiments and practical applications, it is feasible to determine the self-discharge based on the voltage decay in the rest time of the battery.

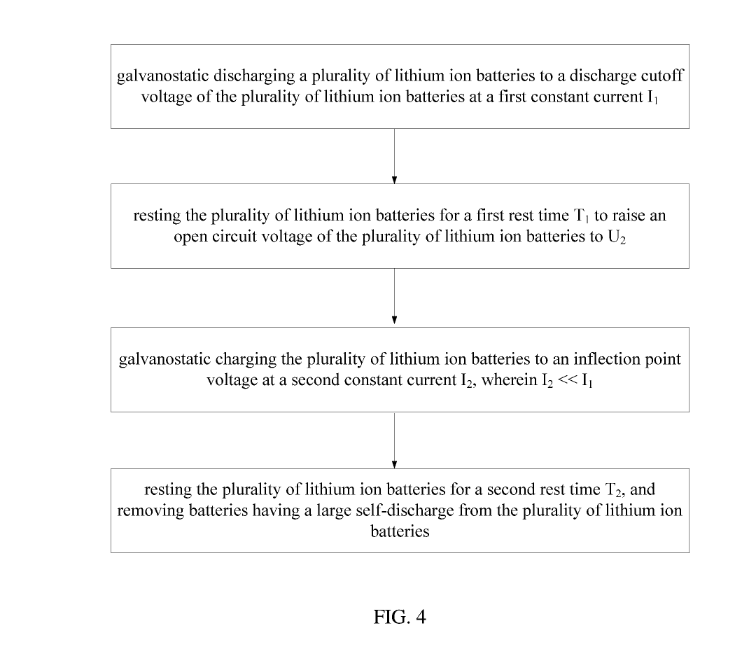

Referring to FIG. 4, a third embodiment of a method for screening a lithium ion battery comprises the following steps:

S30, galvanostatic discharging a plurality of lithium ion batteries to a discharge cutoff voltage of the plurality of lithium ion batteries at a first constant current I₁;

S31, resting the plurality of lithium ion batteries for a first rest time T₁ to raise an open circuit voltage of the plurality of lithium ion batteries to U₂;

S32, galvanostatic charging the plurality of lithium ion batteries to an inflection point voltage at a second constant current I₂, wherein I₂<<I₁; and

S33, resting the plurality of lithium ion batteries for a second rest time T₂, and removing batteries having a large self-discharge from the plurality of lithium ion batteries.

The method for screening a lithium ion battery is similar to the second embodiment, except that the open circuit voltage of the plurality of lithium ion batteries is raised to U₂, and U₂ is smaller than the inflection point voltage in Step 31. In the present embodiment, the open circuit voltage of the lithium ion battery is raised to 3.05 V after the first rest time T₁. Therefore, in the subsequent step S32, the plurality of lithium ion batteries are charged with a small current to the inflection point voltage. Thus the remaining capacity of the lithium ion battery reaches a relatively stable state. The second constant current I₂ is less than or equal to ½ of the first constant current I₁, such as less than ⅓, less than ⅕, and the like. In the present embodiment, the second constant current I₂ is about 2 A. It can be understood that, the second constant current I₂ can be less than 1 A, less than 0.5 A, and the like.

TABLE III
Screening process of lithium iron phosphate

| | | Time | Voltage | Current | Cutoff |
|---|---|---|---|---|---|
| Step. | Process | (min) | (V) | (A) | Current (A) |
| 1 | Rest | 5 | | | |
| 2 | Constant | 100 | 3.0 | 10 | 0.2 |
| | Discharging | | | | |
| 3 | Rest | 5 | | | |
| 4 | Constant | | 3.0 | 2 | |
| | Charging | | | | |

Referring to Table III, after the plurality of lithium ion batteries are completely charged at the second constant current, the plurality of lithium ion batteries are rested for the second rest time, and the lithium ion battery with large self-discharge is picked out and removed.

The method for screening a lithium ion battery fully considers the voltage decay caused by the self-discharge. Through charging and discharging the plurality of lithium ion batteries, the plurality of lithium ion batteries are at the same “starting” line before entering the rest period. During the rest period, the more the voltage decay, the larger the self-discharge. Thus the misjudgment can be reduced. By removing the lithium ion batteries having the large self-discharge, the voltage decay of the lithium-ion batteries in the lithium ion battery module is basically the same, thereby the cycle performance of the lithium ion battery module can be dramatically enhanced.

The embodiments shown and described above are only examples. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and comprising the full extent established by the broad general meaning of the terms used in the claims. It will therefore be appreciated that the embodiments described above may be modified within the scope of the claims.

What is claimed is:

1. A method for screening a lithium ion battery, the method comprising:
galvanostatic discharging a plurality of lithium ion batteries to a discharge cutoff voltage V₀ at a first constant current I₁;
resting the plurality of lithium ion batteries for a first rest time T₁;
galvanostatic charging the plurality of lithium ion batteries to a charge cutoff voltage V₁ at a second constant current I₂; and
resting the plurality of lithium ion batteries for a second rest time T₂, and screening the plurality of lithium ion batteries based on a self-discharge of the plurality of lithium ion batteries.

2. The method of claim 1, wherein the first constant current I₁ is in a range from about 0.5 C to about 1 C.

3. The method of claim 1, wherein the second constant current I₁ is in a range from about 0.5 C to about 1 C.

4. The method of claim 1, wherein when the lithium ion battery reaches the charge cutoff voltage V₁, the lithium ion battery can further be potentio statically charged to a charge cutoff current I₀ in a range from about 0.001 C to about 0.04 C.

5. The method of claim 1, wherein the first rest time T₁ is in a range from 5 minutes to 10 minutes.

6. The method of claim 1, wherein the second rest time T₂ is in a range from about 5 days to about 12 days.

7. The method of claim 1, wherein the screening the plurality of lithium ion batteries comprises removing large self-discharge batteries from the plurality of lithium ion batteries, and the large self-discharge batteries comprise a self-discharge voltage decay of greater than 0.1 V.

8. The method of claim 1, further comprising previously resting the plurality of lithium ion batteries for a predetermined time before galvanostatic discharging the plurality of lithium ion batteries at the first constant current I₁ to have the plurality of lithium ion batteries in a 50% state of charge.

9. The method of claim 8, wherein the resting the plurality of lithium ion batteries for a first rest time T₁ restores an electrochemical system in the plurality of lithium ion batteries to a stable state, and a discharge current of the plurality of lithium ion batteries in the stable state is less than 0.2 mA.

10. A method for screening a lithium ion battery, the method comprising:
galvanostatic discharging a plurality of lithium ion batteries to a discharge cutoff voltage of the plurality of lithium ion batteries at a first constant current I₁;
resting the plurality of lithium ion batteries for a first rest time T₁ to raise an open circuit voltage of the plurality of lithium ion batteries to U₂;
galvanostatic charging the plurality of lithium ion batteries to an inflection point voltage at a second constant current I₂, wherein I₂<<I₁; and
resting the plurality of lithium ion batteries for a second rest time T₂, and removing large self-discharge batteries from the plurality of lithium ion batteries, wherein the large self-discharge batteries comprise a self-discharge voltage decay of greater than 0.1 V.

11. The method of claim 10, wherein the second constant current I₂ is less than or equal to a half of the first constant current I₁.

12. The method of claim 11, wherein the second constant current I₂ is less than or equal to one five of the first constant current I₁.

13. The method of claim 12, wherein the first constant current I₁ is about 10 A, and the second constant current I₂ is about 2 A.

14. The method of claim 10, wherein U₂ is smaller than the inflection point voltage.
